(19) United States
(12) Patent Application Publication
(10) Pub. No.: US 2009/0068341 A1
(43) Pub. Date: Mar. 12, 2009

(54) POSITIVE PHOTORESIST COMPOSITION, THICK FILM PHOTORESIST LAMINATE, METHOD FOR PRODUCING THICK FILM RESIST PATTERN, AND METHOD FOR PRODUCING CONNECTING TERMINAL

(75) Inventors: Koichi Misumi, Kawasaki-shi (JP); Yasushi Washio, Kawasaki-shi (JP); Takahiro Senzaki, Kawasaki-shi (JP); Koji Saito, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 11/909,796

(22) PCT Filed: Mar. 28, 2006
(86) PCT No.: PCT/JP2006/307021

§ 371 Date: Sep. 26, 2007

(30) Foreign Application Priority Data
Mar. 30, 2005 (JP) 2005-99442

(51) Int. Cl. G03F 7/20; G03F 7/09; B05D 5/12

(52) U.S. Cl. 427/58; 430/270.1; 430/326

(57) ABSTRACT

This positive photoresist composition is a positive photoresist composition for exposing to light having one or more wavelengths selected from g-rays, h-rays and i-rays, comprising: (A) a compound which generates an acid under irradiation with active rays or radiation, and (B) a resin whose solubility in an alkali is enhanced by an action of an acid, wherein the component (A) contains an onium salt (A1) having a naphthalene ring in the cation moiety.

### TECHNICAL FIELD

The present invention relates to a positive photoresist composition, a thick film photoresist laminate, a method for producing a thick film resist pattern, and a method for producing a connecting terminal.

This application claims priority from Japanese Patent Application No. 2005-099442 filed on Mar. 30, 2005, the disclosure of which is incorporated by reference herein.

### BACKGROUND ART

With recent downsizing of electronic equipment, there has been a rapid progress toward higher integration of LSIs. To mount LSIs on electronic equipment, a multipin thin film packaging method of providing connection terminals made of protruded electrodes on a support such as substrate is applied. In such a multipin packaging method, a connecting terminal made of bumps protruding from the support, and a connecting terminal comprising a brace referred to as a metal post protruding from the support and a solder ball formed thereon are used.

The bump or metal post can be formed, for example, by forming a thick film resist pattern having a thickness of 5 μm or more on a substrate having a portion made of copper formed on the top face, preferably the face (top face) on which a photoresist layer of a copper substrate is formed, exposing it to light through a required mask pattern, developing it to selectively remove (peel) the portion constituting a connecting terminal, thus forming a resist pattern, embedding a conductor made of copper, gold, nickel or solder into the removed portion (non-resist portion) using a plating technique, and finally removing the resist pattern around the portion.

As a highly sensitive photosensitive resin composition, a chemically amplified photoresist composition using an acid generator is known. In the chemically amplified photoresist composition, an acid is generated from an acid generator under irradiation with radiation. When a heat treatment is conducted after the exposure, generation of the acid is accelerated and thus alkali solubility of a base resin in a resist composition changes. A resist composition which is insoluble in an alkali that is then a made soluble in an alkali is referred to as a positive resist composition, whereas a resist composition which is soluble in an alkali that is then made insoluble in an alkali is referred to as a negative resist Composition. As described above, in the chemically amplified photoresist composition, remarkably high sensitivity is attained as compared with a conventional resist having a photoreaction efficiency (reaction per one photon) of less than 1.

However, when a photoresist layer is formed on a substrate containing copper using a chemically amplified photoresist composition, there arises a problem that high an accuracy resist pattern cannot be obtained because of the adverse influence of copper.

Patent Document 1 (Japanese Unexamined Patent Application, First Publication No. 2003-140347) proposes a technique of laminating a substrate and a thick film photoresist layer containing a resin whose alkali solubility is changed by an action of an acid, and an acid generator, through a layer made of an organic matter which prevents contact between the substrate and the thick film photoresist layer.

### DISCLOSURE OF THE INVENTION

In the above-described method using the shielding layer, the number of steps increases. The method also has a problem in that it is costly.

Since the material of the shielding layer is an organic matter, drying conditions vary depending on the thickness, material and structure of the lower layer of the substrate and thus there arises a problem that the time and temperature must be accurately controlled in the production.

The shielding layer made of an organic matter may be inferior in mixing with the photoresist layer. Mixing refers to a phenomenon wherein adjacent layers are dissolved and intermingled at the interface between adjacent layers when two or more layers are laminated.

Under these circumstances, the present invention has been completed and an object thereof is to provide a positive photoresist composition capable of forming a resist pattern even on a substrate containing copper in the surface on which a photoresist layer is formed, a thick film photoresist laminate, a method for producing a thick film resist pattern, and a method for producing a connecting terminal.

To attain the object described above, the present invention employed the following compositions.

A first aspect of the present invention is directed to a positive photoresist composition for exposing to light having one or more wavelengths selected from g-rays, h-rays and i-rays, comprising:

(A) a compound which generates an acid under irradiation with active rays or radiation, and
(B) a resin whose solubility in an alkali is enhanced by an action of an acid, wherein

a component (A) contains an onium salt (A1) having a naphthalene ring in the cation moiety.

A second aspect of the present invention is directed to a thick film photoresist laminate comprising a substrate and a thick film photoresist layer having a thickness of 10 to 150 μm made of the positive photoresist composition of the present invention, which are laminated with each other.

A third aspect of the present invention is directed to a method for producing a thick film resist pattern, which comprises a lamination step of obtaining the thick film photoresist laminate of the present invention, an exposure step of selectively exposing the thick film photoresist laminate to light having one or more wavelengths selected from g-rays, h-rays and i-rays, and a development step of developing after the exposure step to obtain a thick film resist pattern.

A fourth aspect of the present invention is directed to a method for producing a connecting terminal which comprises a step of forming a connecting terminal made of a conductor at the non-resist portion of the thick film resist pattern obtained by the method for producing a thick film resist pattern of the present invention.

In the present invention, a positive photoresist composition can be provided that is capable of forming a resist pattern even on a substrate containing copper in the surface on which a photoresist layer is formed, a thick film photoresist laminate, a method for producing a thick film resist pattern, and a method for producing a connecting terminal.

### BEST MODE FOR CARRYING OUT THE INVENTION

### Positive Photoresist Composition

The positive photoresist composition of the present invention is a positive photoresist composition for exposing to light having one or more wavelengths selected from g-rays, h-rays and i-rays, comprising:

(A) a compound which generates an acid under irradiation with active ray or radiation [hereinafter referred to as a component (A)], and
(B) a resin whose solubility in an alkali is enhanced by an action of an acid [hereinafter referred to as a component (B)], wherein

the component (A) contains an onium salt (A1) having a naphthalene ring in the cation moiety [hereinafter referred to as a component (A1)].

### Component (A)

First, the component (A1) will be described.

The cation moiety of the component (A1) has one naphthalene ring. The phrase “having a naphthalene ring” means that the component has a structure derived from naphthalene and also means that at least two ring structures and their aromatic properties are maintained. This naphthalene ring may have a substituent such as a linear or branched chain alkyl group having 1 to 4 carbon atoms, hydroxyl group, or linear or branched chain alkoxy group having 1 to 4 carbon atoms. The structure derived from the naphthalene ring may be a monovalent group (one free valency), or a divalent group (two free valencies) or a polyvalent group, but is preferably a monovalent group (provided that the number of free valencies is counted except for the moiety to be bonded with the above substituent). For example, the number of naphthalene rings is from 1 to 3, but is preferably 1 in view of stability of the compound.

The cation moiety of the component (A1) preferably has a structure represented by the following general formula (A1):

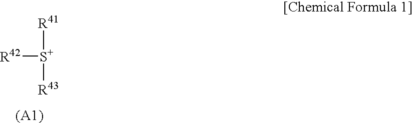

wherein at least one of R⁴, R⁴² and R⁴³ represents a group represented by the following general formula (A1-0) and the others represent a linear or branched chain alkyl group having 1 to 4 carbon atoms, a phenyl group which may have a substituent, a hydroxyl group, or a linear or branched chain alkoxy group having 1 to 4 carbon atoms; or at least one of R⁴¹, R⁴² and R⁴³ represents a group represented by the following general formula (A1-0) and the other two substituents each independently represents a linear or branched chain alkylene group having 1 to 4 carbon atoms, and ends thereof may be combined to form a ring;

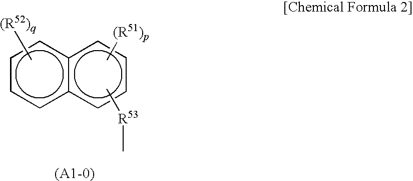

wherein R⁵¹ and R⁵² each independently represents a hydroxyl group, a linear or branched chain alkoxy group having 1 to 4 carbon atoms, or a linear or branched chain alkyl group having 1 to 4 carbon atoms; R⁵³ represents a single bond or a linear or branched chain alkylene group having 1 to 4 carbon atoms which may have a substituent; and p and q each independently represents an integer of 0 or 1 to 2, and p+q is 3 or less and also may be the same or different from each other when a plurality of R⁵¹ exists, or may be the same or different from each other when a plurality of R⁵² exists.

At least one of R⁴¹, R⁴² and R⁴³ is a group represented by the above general formula (A1-0). The number of the group represented by the general formula (A1-0) is preferably 1 in view of stability of the compound.

In the formula represented by the general formula (A1-0), R⁵¹ and R⁵² each independently represents a hydroxyl group, a linear or branched chain alkoxy group having 1 to 4 carbon atoms, or a linear or branched chain alkyl group having 1 to 4 carbon atoms. These substituents are preferable in view of solubility of the component (A) in the resist composition.

P and q each independently represents an integer of 0 or 1 to 2, and p+q is 3 or less.

R⁵³ is a single bond, or a linear or branched chain alkylene group having 1 to 4 carbon atoms which may have a substituent, and is preferably a single bond. The single bond means that the number of carbon atoms is 0.

Examples of the substituent with which the alkylene group is substituted include an oxygen atom (which combines with carbon atoms constituting the alkylene group to form a carbonyl group in this case) and a hydroxyl group.

The others among R⁴¹, R⁴² and R⁴³ represent a linear or branched chain alkyl group having 1 to 4 carbon atoms, or a phenyl group which may have a substituent.

Examples of the substituent with which the phenyl group is substituted include a hydroxyl group, linear or branched chain alkoxy group having 1 to 4 carbon atoms, or linear or branched chain alkyl group having 1 to 4 carbon atoms.

One of R⁴¹, R⁴² and R⁴³ represents a group represented by the following general formula (A1-0) and the other two substituents each independently represents a linear or branched chain alkylene group having 1 to 4 carbon atoms, and ends thereof may be combined to form a ring.

In this case, two alkylene groups described above constitute 3- to 9-membered rings, including a sulfur atom. The number of atoms (including the sulfur atom) constituting the ring is preferably from 5 to 6.

Examples of a preferable cation moiety of the component (A1) include those represented by the following chemical formulas (A1-1) and (A1-2), and a structure represented by the chemical formula (A1-2) is particularly preferable.

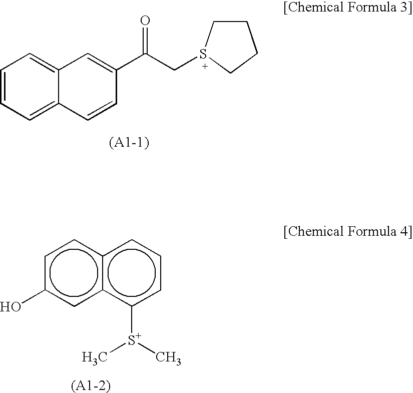

The component (A1) may be either an iodonium salt or a sulfonium salt, but is preferably a sulfonium salt in view of acid generation efficiency.

Therefore, the anion moiety of the component (A1) is preferably an anion capable of forming a sulfonium salt.

Particularly preferred is a fluoroalkylsulfonic acid ion or allylsulfonic acid ion, a portion or all of the hydrogen atoms being fluorinated.

The alkyl group in the fluoroalkylsulfonic acid ion may be a linear, branched or cyclic alkyl group having 1 to 20 carbon atoms. In view of bulkiness of an acid to be generated and its diffusion length, the number of carbon atoms is from 1 to 10. A branched or cyclic alkyl group is particularly preferable because of a short diffusion length.

Specific examples of the alkyl group are a methyl group, ethyl group, propyl group, butyl group and octyl group because they can be synthesized at low cost.

Examples of the aryl group in the allylsulfonic acid include aryl groups having 6 to 20 carbon atoms, which may be substituted or unsubstituted with an alkyl group or a halogen atom, such as a phenyl group and naphthyl group. An aryl group having 6 to 10 carbon atoms is preferable because it can be synthesized at low cost.

Specific examples of a preferable aryl group include a phenyl group, toluenesulfonyl group, ethylphenyl group, naphthyl group and methylnaphthyl group.

The fluorination degree is preferably from 10 to 100%, and more preferably from 50 to 100%. A sulfonate in which all the hydrogen atoms are substituted with a fluorine atom is preferable because acidity is enhanced. Specific examples thereof include trifluoromethane sulfonate, perfluorobutane sulfonate, perfluorooctane sulfonate and perfluorobenzene sulfonate.

Examples of a preferable anion moiety include those represented by the following general formulas (A1-3).

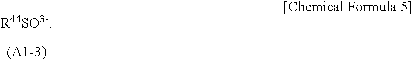

In the general formula (A1-3), examples of R⁴⁴ include structures represented by the following general formulas (A1-4) and (A1-5), and a structure represented by the chemical formula (A1-6):

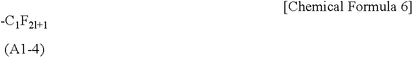

wherein l represents an integer of 1 to 4;

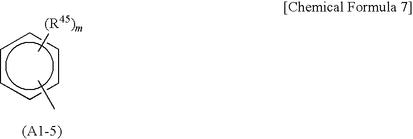

wherein R⁴⁵ represents a hydrogen atom, a hydroxyl group, a linear or branched chain alkyl group having 1 to 4 carbon atoms, or a linear or branched chain alkoxy group having 1 to 4 carbon atoms, and m represents an integer of 1 to 3; and

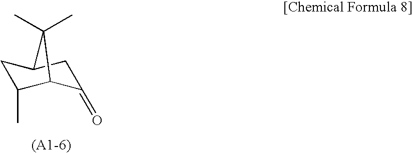

Taking account of safety, trifluoromethanesulfonate and perfluorobutanesulfonate are preferable.

As the anion moiety, those having a structure containing nitrogen can also be used.

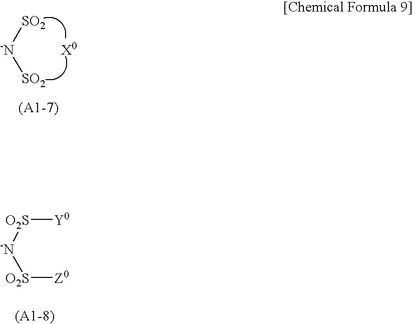

In the formulas (A1-7) and (A1-8), X⁰ represents a linear or branched alkylene group in which at least one hydrogen atom is substituted with a fluorine atom, and the number of carbon atoms of the alkylene group is from 2 to 6, preferably from 3 to 5, and more preferably 3.

Y⁰ and Z⁰ each independently represents a linear or branched alkyl group in which at least one hydrogen atom is substituted with a fluorine atom, and the number of carbon atoms of the alkyl group is from 1 to 10, preferably from 1 to 7, and more preferably from 1 to 3.

The smaller the number of carbon atoms of the alkylene group for X⁰ and the number of carbon atoms of the alkyl group for Y⁰ and Z⁰, the better solubility in a resist solvent, and thus it is preferred.

In the alkylene group for X⁰ and the alkyl group for Y⁰ and Z⁰, the larger the number of hydrogen atoms substituted with a fluorine atom, the more the acidity strengthens, and thus it is preferred. The content of the fluorine atom in the alkylene group or alkyl group, that is, the fluorination degree is preferably from 70 to 100%, and more preferably from 90 to 100%. Most preferred is a perfluoroalkylene group or perfluoroalkyl group in which all hydrogen atoms are substituted with a fluorine atom.

Examples of a preferable component (A1) are listed below.

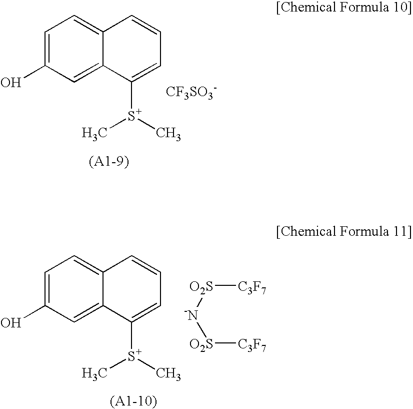

These components (A1) can be used alone or in combination.

The content of the component (A1) in the component (A) is preferably 70% by mass or more, more preferably 80% by mass or more, and most preferably 100% by mass.

Examples of the component which can be used, in addition to the component (A1), in the component (A) [hereinafter referred to as a component (A2)] include the following.

Specific examples thereof include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bistrichloromethyl-6-(3-bromo-4-methoxy)phenyl-s-triazine, 2,4-bistrichloromethyl-6-(2-bromo-4-methoxy)phenyl-s-triazine, 2,4-bistrichloromethyl-6-(2-bromo-4-methoxy)styrylphenyl-s-triazine, 2,4-bistrichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine and tris(2,3-dibromopropyl)-1,3,5-triazine, and halogen-containing triazine compounds represented by the general formula (A2-1) such as tris(2,3-dibromopropyl)isocyanurate;

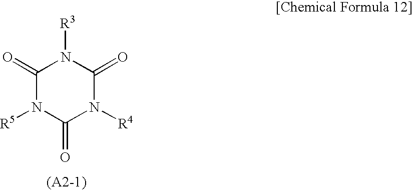

wherein R³ to R⁵ each may be the same or different and represents a halogenated alkyl group; α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile, α-(ethylsulfonyloxyimino)-1-cyclopentenylacetonitrile, and a compound represented by the following general formula (A2-2):

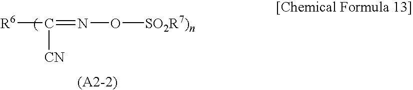

wherein R⁶ represents a mono-, di- or trivalent organic group, R⁷ represents a substituted or unsubstituted saturated hydrocarbon group, an unsaturated hydrocarbon group or an aromatic compound group, n represents a natural number of 1 to 3, the aromatic compound group as used herein means a group of a compound which exhibits physical and chemical properties unique to the aromatic compound and examples thereof include aromatic hydrocarbon groups such as a phenyl group and naphthyl group and heterocyclic groups such as a furyl group and thienyl group, and also these groups may have one or more suitable substituents such as a halogen atom, alkyl group, alkoxy group and nitro group on the ring, R⁷ is particularly preferably an alkyl group having 1 to 4 carbon atoms and examples thereof include a methyl group, ethyl group, propyl group and butyl group, a compound in which R⁶ is an aromatic compound group and R⁷ is a lower alkyl group is particularly preferable, examples of an acid generator represented by the above formula include compounds in which R⁶ is a phenyl group, a methylphenyl group or a methoxyphenyl group and R⁷ is a methyl group, when n=1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, and specific examples of the acid generator represented by the above general formula include acid generators represented by the following chemical formula, when n=2:

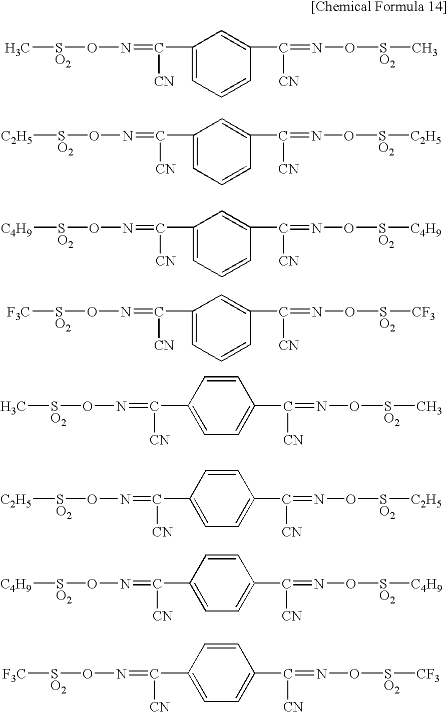

bissulfonyl diazomethanes such as bis(p-toluenesulfonyl)diazomethane, bis(1,1-dimethylethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonic acid esters such as pyrogallol trimesylate, pyrogallol tritosylate, benzyl tosylate, benzyl sulfonate, N-methylsulfonyloxy succinimide, N-trichloromethylsulfonyloxy succinimide, N-phenylsulfonyloxy maleimide and N-methylsulfonyloxy phthalimide; trifluoromethanesulfonic acid esters such as N-hydroxyphthalimide and N-hydroxynaphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate and (p-tert-butylphenyl)diphenylsulfonium trifluoromethanesulfonate; benozin tosylates such as benozin tosylate and α-methylbenozin tosylate; and other diphenyliodonium salts, triphenylsulfonium salts, phenyldiazonium salts and benzyl carbonates.

The component (A2) is preferably a compound having at least two oximesulfonate groups represented by the general formula (A2-3):

R—SO₂O—N═C(CN)— (A2-3)

wherein R represents a substituted or non-substituted alkyl or allyl group having 1 to 8 carbon atoms, and particularly preferably a compound represented by the general formula (A2-4):

R—SO₂O—N═C(CN)-A-C(CN)═N—OSO₂—R (A2-4)

wherein A represents a divalent substituted or unsubstituted alkylene or aromatic compound group having 1 to 8 carbon atoms, and R represents a substituted or non-substituted alkyl or allyl group having 1 to 8 carbon atoms. The aromatic compound group as used herein refers to a group of a compound which exhibits physical and chemical properties unique to an aromatic compound, and examples thereof include aromatic hydrocarbon groups such as a phenyl group and naphthyl group, and heterocyclic groups such as a furyl group and thienyl group. These aromatic compound groups may have at least one suitable substituent such as a halogen atom, alkyl group, alkoxy group or nitro group on the ring. It is further preferred that, in the above general formula, A represents a phenylene group, and R represents a lower alkyl group having 1 to 4 carbon atoms.

The components (A2) may be used alone or in combination.

The content of the component (A) is from 0.1 to 20 parts by mass, and preferably from 0.2 to 10 parts by mass, based on 100 parts by mass of the total mass of the component (B) and the optional component (C) which is described hereinafter. When the content is 0.1 parts by mass or more, it becomes possible to obtain sufficient sensitivity. On the other hand, when the content is 20 parts by mass or less, a uniform solution is obtained because of good solubility in a solvent, and thus storage stability may be improved.

### Component (B)

The component (B) is not specifically limited as long as it can be used in a resist composition and examples of a preferable component include those described in Japanese Unexamined Patent Application, First Publication No. 2004-309775, Japanese Unexamined Patent Application, First Publication No. 2004-309776, Japanese Unexamined Patent Application, First Publication No. 2004-309777 and Japanese Unexamined Patent Application, First Publication No. 2004-309778.

It is preferable to use one, or two or more kinds selected from the following components (B1), (B2) and (B3).

The component (B1) is a resin made of a copolymer comprising a constituent unit (hereinafter referred to as a unit (b1-1)) represented by the following general formula (b1-1):

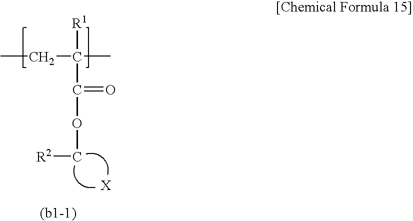

wherein R¹ represents a hydrogen atom or a methyl group, R² represents a lower alkyl group, and X is combined with carbon atoms to which it is attached to form a hydrocarbon ring having 5 to 20 carbon atoms.
Unit (b1-1)

The unit (b1-1) is a constituent unit represented by the above general formula (b1-1).

In the general formula (b1-1), R¹ is a hydrogen atom or a methyl group.

The lower alkyl group represented by R² may be either linear or branched and examples thereof include a methyl group, ethyl group, n-propyl group, isopropyl group, n-butyl group, isobutyl group, sec-butyl group, tert-butyl group, and various pentyl groups. Among these lower alkyl groups, a lower alkyl group having 2 to 4 carbon atoms is preferable in view of high contrast, good resolution and good depth of focus.

X is combined with carbon atoms to which it is attached to form a monocyclic or polycyclic hydrocarbon ring having 5 to 20 carbon atoms.

Examples of the monocyclic hydrocarbon ring include cyclopentane, cyclohexane, cycloheptane and cyclooctane rings.

Examples of the polycyclic hydrocarbon ring include dicyclic hydrocarbon ring, tricyclic hydrocarbon ring and tetracyclic hydrocarbon ring. Specific examples thereof include polycyclic hydrocarbon rings such as adamantane, norbornane, isobornane, tricyclodecane and tetracyclododecane rings.

As the hydrocarbon ring having 5 to 20 carbon atoms, which is formed by combining X with carbon atoms to which it is attached, a cyclohexane ring and an adamantane ring are particularly preferable.

Specific examples of a preferable constituent unit represented by the above general formula (b1-1) include the following ones expressed by the general formulae (b1-1a), (b1-1b) and (b1-1c), respectively.

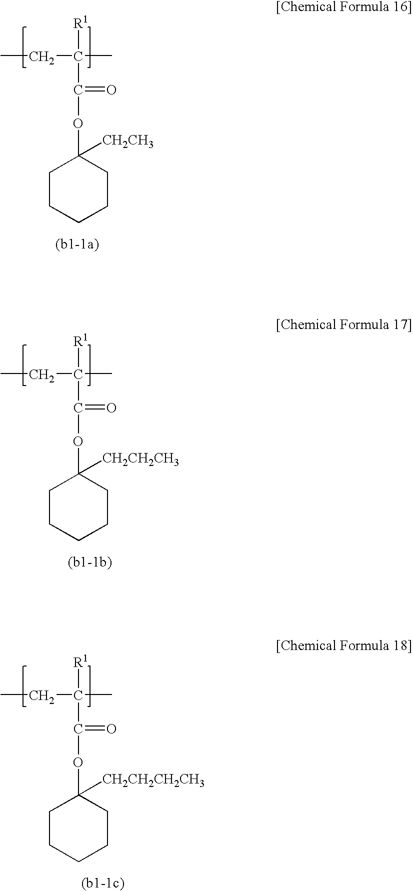

As the unit (b1-1), for example, one unit among constituent units represented by the general formula (b1-1) may be used, but two or more constituent units having different structures may also be used.

Furthermore, the component (B1) is preferably a resin made of a copolymer comprising the above constituent unit (b1-1), and a constituent unit (b1-2) derived from a polymerizable compound having an ether bond. Adhesion with the substrate upon development and plating solution resistance are improved by containing the unit (b1-2).

Unit (b1-2)

The unit (b1-2) is a constituent unit derived from a polymerizable compound having an ether bond.

Examples of the polymerizable compound having an ether bond include radical polymerizable compounds, for example, (meth)acrylic acid derivatives having an ether bond and an ester bond, such ads 2-methoxyethyl(meth)acrylate, 2-ethoxyethyl(meth)acrylate, methoxytriethylene glycol (meth)acrylate, 3-methoxybutyl(meth)acrylate, ethylcarbitol (meth)acrylate, phenoxypolyethylene glycol (meth)acrylate, methoxypolypropylene glycol (meth)acrylate and tetrahydrofurfuryl(meth)acrylate. Among these compounds, 2-methoxyethyl(meth)acrylate, 2-ethoxyethyl(meth)acrylate and methoxytriethylene glycol (meth)acrylate are preferable. These compounds can be used alone or in combination.

Furthermore, the component (B1) can contain the other polymerizable compound as a monomer for the purpose of appropriately controlling physical and chemical characteristics. As used herein, “the other polymerizable compound” means a polymerizable compound other than the units (b1-1) and (b1-2) described above. Examples of the polymerizable compound include known radical polymerizable compounds and anionic polymerizable compounds. Specific examples thereof include radical polymerizable compounds, for example, monocarboxylic acids such as acrylic acid, methacrylic acid and crotonic acid, dicarboxylic acids such as maleic acid, fumaric acid and itaconic acid, and methacrylic acid derivatives having a carboxyl group and an ester bond such as 2-methacryloyloxyethylsuccinic acid, 2-methacryloyloxyethylmaleic acid, 2-methacryloyloxyethylphthalic acid and 2-methacryloyloxyethylhexahydrophthalic acid; (meth)acrylic acid alkyl esters such as methyl(meth)acrylate, ethyl (meth)acrylate and butyl(meth)acrylate; (meth)acrylic acid hydroxyalkyl esters such as 2-hydroxyethyl(meth)acrylate and 2-hydroxypropyl(meth)acrylate; (meth)acrylic acid aryl ester such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

The content of the unit (b1-1) in the component (B1) is preferably from 10 to 90% by mass, and more preferably from 30 to 70% by mass. When the content is controlled to 90% by mass or less, sensitivity can be improved. On the other hand, when the content is controlled to 10% by mass or more, a decrease in residual film rate can be suppressed.

The content of the unit (b1-2) in the component (B1) is preferably from 10 to 90% by mass, and more preferably from 30 to 70% by mass. When the content is 90% by mass or less, a decrease in residual film rate can be suppressed. On the other hand, when the content is controlled to 10% by mass or more, adhesion with the substrate upon development and plating solution resistance can be improved.

The polystyrene equivalent mass average molecular weight (hereinafter referred to as a mass average molecular weight) of the component (B1) is preferably from 10,000 to 600,000, more preferably from 20,000 to 600,000, and still more preferably from 30,000 to 550,000. When the mass average molecular weight is 600,000 or less, deterioration of peelability can be suppressed. On the other hand, when the mass average molecular weight is 10,000 or more, the resulting resist film can have sufficient strength. Also bulging of a profile and cracking upon plating can be suppressed.

When the mass average molecular weight is 230,000 or less, cracking resistance is improved.

Since the component (B1) contains the unit (b1-1), a change in dissolution (contrast) to an alkali before and after the exposure is high.

Furthermore, the component (B1) is preferably a resin having a dispersion degree of 1.05 or more. As used herein, the dispersion degree refers to a value obtained by dividing a mass average molecular weight by a number average molecular weight. When the dispersion degree is 1.05 or more, stress resistance to plating deteriorates, and thus a tendency of bulging of a metal layer obtained by a plating treatment can be suppressed.

The component (B2) is a resin made of a copolymer comprising a constituent unit (hereinafter referred to as a unit (b2-1)) represented by the following general formula (b2-1):

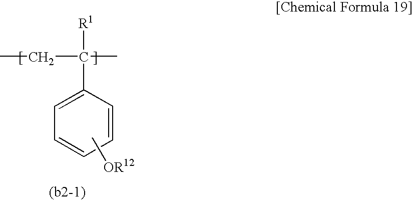

wherein R¹ represents a hydrogen atom or a methyl group, and R¹² represents an acid-unstable group.
Unit (b2-1)

The unit (b2-1) is a constituent unit represented by the above general formula (b2-1).

In the general formula (b2-1), R¹ is a hydrogen atom or a methyl group.

R¹² is an acid-unstable group. The acid-unstable group is selected from various acid-unstable groups, and is particularly preferably a group represented by the following general formula (b2-6) or (b2-7), a linear, branched or cyclic alkyl group having 1 to 6 carbon atoms, a tetrahydropyranyl group, a tetrafuranyl group, or a trialkylsilyl group.

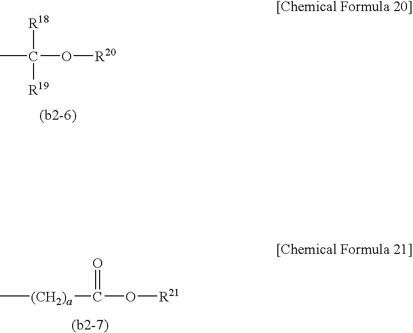

wherein R¹⁸ and R¹⁹ each independently represents a hydrogen atom or a linear or branched alkyl group having 1 to 6 carbon atoms; R²⁰ represents a linear, branched or cyclic alkyl group having 1 to 10 carbon atoms; R²¹ represents a linear, branched or cyclic alkyl group having 1 to 6 carbon atoms; and a represents 0 or 1.

Examples of the linear, branched or alkyl group include a methyl group, ethyl group, propyl group, isopropyl group, n-butyl group, iso-butyl group and tert-butyl group, and examples of the cyclic alkyl group include a cyclohexyl group.

Examples of the acid-unstable group represented by the above formula (b2-6) include a methoxyethyl group, ethoxyethyl group, n-propoxyethyl group, iso-propoxyethyl group, n-butoxyethyl group, iso-butoxyethyl group, tert-butoxyethyl group, cyclohexyloxyethyl group, methoxypropyl group, ethoxypropyl group, 1-methoxy-1-methyl-ethyl group and 1-ethoxy-1-methyl-ethyl group, and examples of the acid-unstable group represented by the above formula (b2-7) include a tert-butoxycarbonyl group and tert-butoxycarbonylmethyl group. Examples of the trialkylsilyl group include those in which each alkyl group has 1 to 6 carbon atoms, such as a trimethylsilyl group and tri-tert-butyldimethylsilyl group.

As the unit (b2-1), one unit among constituent units represented by the above general formula (b2-1) may be used, but two or more constituent units having different structures may also be used.

The content of the unit (b2-1) in the component (B2) is preferably from 5 to 95% by mass, and more preferably from 10 to 90% by mass. When the content is 95% by mass or less, sensitivity can be improved. On the other hand, when the content is 5% by mass or more, a decrease in residual film rate can be suppressed.

Furthermore, the component (B2) can contain another polymerizable compound as a monomer for the purpose of appropriately controlling physical and chemical characteristics. As used herein, “another polymerizable compound” refers to a polymerizable compound other than the unit (b2-1). Examples of the polymerizable compound include known radical polymerizable compounds and anionic polymerizable compounds. Specific examples thereof include radical polymerizable compounds, for example, monocarboxylic acids such as acrylic acid, methacrylic acid and crotonic acid, dicarboxylic acids such as maleic acid, fumaric acid and itaconic acid, and methacrylic acid derivatives having a carboxyl group and an ester bond such as 2-methacryloyloxyethylsuccinic acid, 2-methacryloyloxyethylmaleic acid, 2-methacryloyloxyethylphthalic acid and 2-methacryloyloxyethylhexahydrophthalic acid; (meth)acrylic acid alkyl esters such as methyl(meth)acrylate, ethyl (meth)acrylate and butyl(meth)acrylate; (meth)acrylic acid hydroxyalkyl esters such as 2-hydroxyethyl(meth)acrylate and 2-hydroxypropyl(meth)acrylate; (meth)acrylic acid aryl ester such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

Furthermore, the component (B2) is preferably a resin having a dispersion degree of 1.05 or more. As used herein, the dispersion degree refers to a value obtained by dividing a mass average molecular weight by a number average molecular weight. When the dispersion degree is 1.05 or more, stress resistance to plating deteriorates, and thus a tendency of bulging of a metal layer obtained by a plating treatment can be suppressed.

The component (B3) contains (b3-1) a resin comprising a constituent unit represented by the following general formula (b3-1) (hereinafter referred to as a component (b3-1)), and (b3-2) a resin comprising a constituent unit represented by the following general formula (b3-2) (hereinafter referred to as a component (b3-2)).

Component (b3-1): The component (b3-1) comprises a constituent unit represented by the following formula (b3-1):

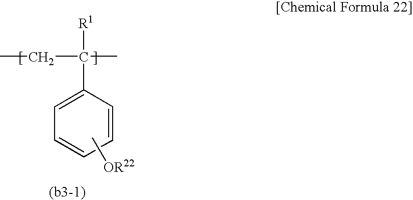

wherein R¹ represents a hydrogen atom or methyl group, and R²² represents an acid-unstable group.

In the above general formula (b3-1), R¹ is a hydrogen atom or a methyl group.

R²² is an acid-unstable group. The acid-unstable group is selected from various acid-unstable groups, and is particularly preferably a group represented by the following general formula (b3-7) or (b3-8), a linear, branched or cyclic alkyl group having 1 to 6 carbon atoms, a tetrahydropyranyl group, a tetrafuranyl group, or a trialkylsilyl group.

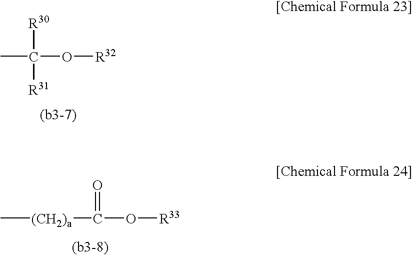

wherein R³⁰ and R³¹ each independently represents a hydrogen atom or a linear or branched alkyl group having 1 to 6 carbon atoms; R³² represents a linear, branched or cyclic alkyl group having 1 to 10 carbon atoms; R³³ represents a linear, branched or cyclic alkyl group having 1 to 6 carbon atoms; and a represents 0 or 1.

Examples of the linear or branched alkyl group include a methyl group, ethyl group, propyl group, isopropyl group, n-butyl group, iso-butyl group and tert-butyl group, and examples of the cyclic alkyl group include a cyclohexyl group.

Examples of the acid-unstable group represented by the above formula (b3-7) include a methoxyethyl group, ethoxyethyl group, n-propoxyethyl group, iso-propoxyethyl group, n-butoxyethyl group, iso-butoxyethyl group, tert-butoxyethyl group, cyclohexyloxyethyl group, methoxypropyl group, ethoxypropyl group, 1-methoxy-1-methyl-ethyl group and 1-ethoxy-1-methyl-ethyl group, and examples of the acid-unstable group represented by the above formula (b3-8) include a tert-butoxycarbonyl group and tert-butoxycarbonylmethyl group. Examples of the trialkylsilyl group include those in which each alkyl group has 1 to 6 carbon atoms, such as a trimethylsilyl group and tri-tert-butyldimethylsilyl group.

The component (b3-1) may contain one unit among constituent units represented by the above general formula (b3-1), but may contain two or more constituent units having different structures.

Furthermore, the component (b3-1) can contain the other polymerizable compound as a monomer for the purpose of appropriately controlling physical and chemical characteristics. As used herein, “the polymerizable compound” refers to a polymerizable compound other than the unit (b3-1). Examples of the polymerizable compound include known radical polymerizable compounds and anionic polymerizable compounds. Specific examples thereof include radical polymerizable compounds, for example, monocarboxylic acids such as acrylic acid, methacrylic acid and crotonic acid, dicarboxylic acids such as maleic acid, fumaric acid and itaconic acid, and methacrylic acid derivatives having a carboxyl group and an ester bond such as 2-methacryloyloxyethylsuccinic acid, 2-methacryloyloxyethylmaleic acid, 2-methacryloyloxyethylphthalic acid and 2-methacryloyloxyethylhexahydrophthalic acid; (meth)acrylic acid alkyl esters such as methyl(meth)acrylate, ethyl (meth)acrylate and butyl(meth)acrylate; (meth)acrylic acid hydroxyalkyl esters such as 2-hydroxyethyl(meth)acrylate and 2-hydroxypropyl(meth)acrylate; (meth)acrylic acid aryl ester such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

Component (b3-2): The component (b3-2) is a resin comprising a constituent unit represented by the following general formula (b3-2):

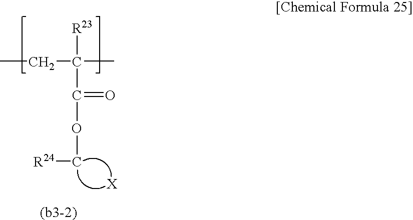

wherein R²³ represents a hydrogen atom or a methyl group; R²⁴ represents an alkyl group having 1 to 4 carbon atoms; and X is combined with carbon atoms to which it is attached to form a hydrocarbon ring having 5 to 20 carbon atoms.

In the above general formula (b3-2), R²³ is a hydrogen atom or a methyl group.

The lower alkyl group represented by R²⁴ may be either linear or branched and examples thereof include a methyl group, ethyl group, n-propyl group, isopropyl group, n-butyl group, isobutyl group, sec-butyl group, tert-butyl group, and various pentyl groups. Among these lower alkyl groups, a lower alkyl group having 2 to 4 carbon atoms is preferable in view of high contrast, good resolution and good depth of focus.

X is combined with carbon atoms to which it is attached to form a monocyclic or polycyclic hydrocarbon ring having 5 to 20 carbon atoms.

Examples of the monocyclic hydrocarbon ring include cyclopentane, cyclohexane, cycloheptane and cyclooctane rings.

Examples of the polycyclic hydrocarbon ring include a dicyclic hydrocarbon ring, tricyclic hydrocarbon ring and tetracyclic hydrocarbon ring. Specific examples thereof include polycyclic hydrocarbon rings such as adamantane, norbornane, isobornane, tricyclodecane and tetracyclododecane rings.

As the hydrocarbon ring having 5 to 20 carbon atoms, which is formed by combining X with carbon atoms to which it is attached, a cyclohexane ring and an adamantane ring are particularly preferable.

The component (b3-2) may comprise a least one from among constituent units represented by the above general formula (b3-2), but may comprise two or more constituent units having different structures.

It is preferred that the component (b3-2) further comprises a constituent unit derived from a polymerizable compound having an ether bond. Adhesion with the substrate upon development and plating solution resistance are improved by containing the constituent unit.

Examples of the polymerizable compound having an ether bond include radical polymerizable compounds, for example, (meth)acrylic acid derivatives having an ether bond and an ester bond, such as 2-methoxyethyl(meth)acrylate, 2-ethoxyethyl(meth)acrylate, methoxytriethylene glycol (meth)acrylate, 3-methoxybutyl(meth)acrylate, ethylcarbitol (meth)acrylate, phenoxypolyethylene glycol (meth)acrylate, methoxypolypropylene glycol (meth)acrylate and tetrahydrofurfuryl(meth)acrylate. Among these compounds, 2-methoxyethyl(meth)acrylate, 2-ethoxyethyl(meth)acrylate and methoxytriethylene glycol (meth)acrylate are preferable. These compounds can be used alone or in combination.

Furthermore, the component (b3-2) can contain another polymerizable compound as a monomer for the purpose of appropriately controlling physical and chemical characteristics. As used herein, “another polymerizable compound” means a polymerizable compound other than the constituent unit (b3-2) described above and the constituent unit derived from the polymerizable compound having an ether bond. Examples of the polymerizable compound include known radical polymerizable compounds and anionic polymerizable compounds. Specific examples thereof include radical polymerizable compounds, for example, monocarboxylic acids such as acrylic acid, methacrylic acid and crotonic acid, dicarboxylic acids such as maleic acid, fumaric acid and itaconic acid, and methacrylic acid derivatives having a carboxyl group and an ester bond such as 2-methacryloyloxyethylsuccinic acid, 2-methacryloyloxyethylmaleic acid, 2-methacryloyloxyethylphthalic acid and 2-methacryloyloxyethylhexahydrophthalic acid; (meth)acrylic acid alkyl esters such as methyl(meth)acrylate, ethyl (meth)acrylate and butyl(meth)acrylate; (meth)acrylic acid hydroxyalkyl esters such as 2-hydroxyethyl(meth)acrylate and 2-hydroxypropyl(meth)acrylate; (meth)acrylic acid aryl ester such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

The mass average molecular weight of the component (b3-2) is preferably 500,000 or less, and more preferably 400,000 or less. When the mass average molecular weight is 500,000 or less, deterioration of peelability can be suppressed. The mass average molecular weight of the component (b3-2) is preferably 10,000 or more, and more preferably 30,000 or more. When the mass average molecular weight is 10,000 or more, the resulting resist film has sufficient strength. Therefore, bulging of a profile and cracking upon plating can be prevented.

By using the components (b3-1) and (b3-2) in combination, a change in dissolution (contrast) to an alkali before and after the exposure is high, and thus developing properties and resolution are improved.

The amount of the component (B) is preferably from 5 to 95 parts by mass, and more preferably from 10 to 90 parts by mass, based on 100 parts by mass of the total mass of the components (B) and (C). The amount is preferably 5 parts by mass or more because cracking hardly arises upon plating. The amount is preferably 95 parts by mass or less because sensitivity may be improved.

The positive photoresist composition of the present invention preferably contains (C) an alkali soluble resin [referred to as a component (C)].

As the component (C), any one can be appropriately selected and used from those which have conventionally been known as an alkali-soluble resin in a chemically amplified photoresist.

It is particularly preferable to contain one or more resins selected from (c1) a novolak resin, (c2) a copolymer comprising a hydroxystyrene constituent unit and a styrene constituent unit, (c3) an acrylic resin, and (c4) a vinyl resin, and it is preferable to contain (c1) a novolak resin and/or (c2) a copolymer of a hydroxystyrene constituent unit and a styrene constituent unit. This is because it is easy to control coatability and developing rate.

(c1) Novolak Resin

The novolak resin as the component (c1) is obtained by addition condensation of an aromatic compound having a phenolic hydroxyl group (hereinafter merely referred to as “phenols”) and aldehydes in the presence of an acid catalyst.

Examples of the phenols to be used include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone monomethyl ether, pyrogallol, fluoroglycinol, hydroxydiphenyl, bisphenol A, gallic acid, gallic acid ester, α-naphthol and β-naphthol.

Examples of the aldehydes include formaldehyde, furfural, benzaldehyde, nitrobenzaldehyde and acetoaldehyde.

The catalyst used in the addition condensation reaction is not specifically limited. As the acid catalyst, for example, hydrochloric acid, nitric acid, sulfuric acid, formic acid, oxalic acid and acetic acid can be used.

A novolak resin using only m-cresol as phenols is particularly excellent in development profile and is therefore preferable.

(c2) Copolymer Comprising Hydroxystyrene Constituent Unit and Styrene Constituent Unit

The component (c2) is a copolymer comprising at least a hydroxystyrene constituent unit and a styrene constituent unit. That is, it is a copolymer comprising a hydroxystyrene constituent unit and a styrene constituent unit, or a copolymer comprising a hydroxystyrene constituent unit and a styrene constituent unit, and a constituent unit other than these.

Examples of the hydroxystyrene constituent unit include hydroxystyrene constituent unit, for example, hydroxystyrenes such as p-hydroxystyrene, and α-alkylhydroxystyrene such as α-methylhydroxystyrene and α-ethylhydroxystyrene.

Examples of the styrene constituent unit include styrene, chlorostyrene, chloromethylstyrene, vinyltoluene and α-methylstyrene.

(c3) Acrylic Resin

The acrylic resin as the component (c3) is not specifically limited as long as it is an alkali-soluble acrylic resin, and an acrylic resin comprising a constituent unit derived from a polymerizable compound having an ether bond and a constituent unit derived from a polymerizable compound having a carboxyl group is particularly preferable.

Examples of the polymerizable compound having an ether bond include (meth)acrylic acid derivatives having an ether bond and an ester, such as 2-methoxyethyl(meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate and tetrahydrofurfuryl(meth)acrylate, and 2-methoxyethyl acrylate, methoxytriethylene glycol acrylate are preferable. These compounds can be used alone or in combination.

Examples of the polymerizable compound having a carboxyl group include monocarboxylic acids such as acrylic acid, methacrylic acid and crotonic acid; dicarboxylic acids such as maleic acid, fumaric acid and itaconic acid; and compounds having a carboxyl group and an ester bond, such as 2-methacryloyloxyethylsuccinic acid, 2-methacryloyloxyethylmaleic acid, 2-methacryloyloxyethylphthalic acid and 2-methacryloyloxyethylhexahydrophthalic acid. Among these compounds, acrylic acid and methacrylic acid are preferable. These compounds can be used alone or in combination.

(c4) Vinyl Resin

The vinyl resin as the component (c4) is a poly(vinyl lower alkyl ether) and comprises a (copolymer obtained by polymerizing a vinyl lower alkyl ether represented by the following general formula (C1) alone or a mixture of two or more kinds of these.

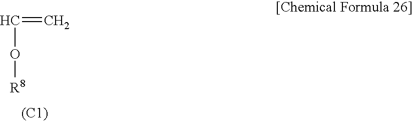

wherein R⁸ represents a linear or branched alkyl group having 1 to 5 carbon atoms.

In the general formula (C1), examples of the linear or branched alkyl group having 1 to 5 carbon atoms include a methyl group, ethyl group, n-propyl group, i-propyl group, n-butyl group, i-butyl group, n-pentyl group and i-pentyl group. Among these alkyl groups, a methyl group, an ethyl group and an i-butyl group are preferable, and a methyl group is particularly preferable. In the present invention, a particularly preferable poly(vinyl lower alkyl ether) is poly(vinyl methyl ether).

The content of the component (C) is from 5 to 95 parts by mass, and preferably from 10 to 90 parts by mass, based on 100 parts by mass of the total mass of the components (B) and (C). When the content is 5 parts by mass or more, cracking resistance can be improved. On the other hand, when the content is 95 parts by mass or less, thickness loss upon development may be prevented.

It is preferred that the positive photoresist composition of the present invention further contains (D) an acid diffusion inhibitor [hereinafter referred to as a component (D)] for the purpose of improving the resist pattern profile and post exposure stability of the latent image formed by the pattern-wise exposure of the resist layer.

As the component (D), any one can be appropriately selected and used from those which have conventionally been known as an acid diffusion inhibitor in a chemically amplified photoresist. It is particularly preferable to contain (d1) a nitrogen-containing compound. If necessary, it is possible to contain (d2) an organic carboxylic acid, or an oxo acid of phosphorus or derivative thereof.

(d1) Nitrogen-containing compound: Examples of the nitrogen-containing compound as the component (d1) include trimethylamine, diethylamine, triethylamine, di-n-propylamine, tri-n-propylamine, tribenzylamine, diethanolamine, triethanolamine, n-hexylamine, n-heptylamine, n-octylamine, n-nonylamine, ethylenediamine, N,N,N′,N′-tetramethylethylenediamine, tetramethylenediamine, hexamethylenediamine, 4,4′-diaminodiphenylmethane, 4,4′-diaminodiphenylether, 4,4′-diaminobenzophenone, 4,4′-diaminodiphenylamine, formamide, N-methylformamide, N,N-dimethyl formamide, acetamide, N-methylacetamide, N,N-dimethyl acetamide, propionamide, benzamide, pyrrolidone, N-methylpyrrolidone, methylurea, 1,1-dimethylurea, 1,3-dimethylurea, 1,1,3,3-tetramethylurea, 1,3-diphenylurea, imidazole, benzimidazole, 4-methylimidazole, 8-oxyquinoline, acridine, purine, pyrrolidine, piperidine, 2,4,6-tri(2-pyridyl)-S-triazine, morpholine, 4-methylmorpholine, piperazine, 1,4-dimethylpiperazine and 1,4-diazabicyclo[2.2.2]octane.

Among these compounds, an alkanolamine such as triethanolamine is preferable.

These compounds may be used alone or in combination.

The component (d1) is usually used an amount within a range from 0 to 5 parts by mass, and particularly preferably from 0 to 3 parts by mass, based on 100 parts by mass of the total mass of the component (B) and optional component (C).

(d2) Organic Carboxylic Acid, or Oxo Acid of Phosphorus or Derivative Thereof

The organic carboxylic acid is preferably malonic acid, citric acid, malic acid, succinic acid, benzoic acid or salicylic acid, and particularly preferably salicylic acid.

Examples of the oxo acid of phosphorus or derivative thereof include phosphoric acid or a derivative such as ester thereof, for example, phosphoric acid, di-n-butyl phosphate or diphenyl phosphate; phosphonic acid or derivative such as ester thereof, for example, phosphonic acid, dimethyl phosphonate, di-n-butyl phosphonate, phenylphosphonic acid, diphenyl phosphonate or dibenzyl phosphonate; and phosphinic acid or a derivative such as an ester thereof, for example, phosphinic acid or phenylphosphinic acid. Among these compounds, phosphonic acid is preferable.

These compounds may be used alone or in combination.

The component (d2) is usually used in an amount within a range from 0 to 5 parts by mass, and particularly from 0 to 3 parts by mass, based on 100 parts by mass of the total mass of the component (B) and optional component (C).

The component (d2) is preferably used in the same amount as that of the component (d1). This is because the components (d2) and (d1) form a salt, resulting in stabilization.

If necessary, the positive photoresist composition of the present invention may contain miscible additives, for example, conventional additive resins, plasticizers, bonding auxiliaries, stabilizers, colorants and surfactants, which are used for improving performance of the resist film.

The positive photoresist composition can be appropriately mixed with organic solvents so as to adjust viscosity.

Specific examples of the organic solvent include ketones such as acetone, methyl ethyl ketone, cyclohexanone, methyl isoamyl ketone and 2-heptanone; polyhydric alcohols and derivatives thereof, such as ethylene glycol, ethylene glycol monoacetate, diethylene glycol, diethylene glycol monoacetate, propylene glycol, propylene glycol monoacetate, and monomethyl ether, monoethyl ether, monopropyl ether, monobutyl ether and monophenyl ether of dipropylene glycol or dipropylene glycol monoacetate; cyclic ethers such as dioxane; and esters such as methyl lactate, ethyl lactate, methyl acetate, ethyl acetate, butyl acetate, methyl pyruvate, ethyl pyruvate, methyl methoxypropionate and ethyl ethoxypropionate. These organic solvents may be used alone or in combination.

To obtain a film having a thickness of 10 μm or more using a spin coating method, the amount of the solvent is adjusted so as to control the solid content in the positive photoresist composition within a range from 30 to 65% by mass. When the solid content is less than 30% by mass, it is difficult to obtain a thick film suited for the production of a connecting terminal. On the other hand, when the solid content is more than 65% by mass, fluidity of the composition drastically deteriorates, and thus it is difficult to handle and to obtain a uniform resist film by the spin coating method.

The positive photoresist composition may be prepared, for example, by only mixing the above respective components under stirring using a conventional method, or dispersing and mixing the components using a disperser such as a dissolver, homogenizer or three roll mill, if necessary. After mixing, the resulting mixture may be further filtered using a mesh or a membrane filter.

The positive photoresist composition of the present invention is suited for formation of a thick film photoresist layer having a thickness within a range from 10 to 150 μm, more preferably from 20 to 120 μm, and still more preferably from 20 to 80 μm, on a substrate.

### [Thick Film Photoresist Laminate]

The thick film photoresist laminate of the present invention comprises a substrate, and a thick film photoresist layer made of the positive photoresist composition of the present invention, which is laminated on the substrate.

The substrate is not specifically limited and a conventionally known substrate can be used, and examples thereof include a substrate for electronic components and substrate having a predetermined wiring pattern formed thereon. Examples of the substrate include substrates made of silicon, silicon nitride, or substrates made of metals such as, titanium, tantalum, palladium, titaniumtungsten, copper, chromium, iron and aluminum; and a glass substrate. As the material for the wiring pattern, for example, copper, solder, chromium, aluminum, nickel and gold can be used.

The positive photoresist composition of the present invention is characterized in that, even when using a substrate in which copper exists in the surface on which a photoresist layer is formed, a trailing phenomenon between the pattern and the substrate is less likely to occur and a usable resist pattern can be obtained.

Examples of the substrate in which copper exists in the surface on which a photoresist layer is formed include a copper substrate, copper sputter substrate, and substrate having copper wiring. The substrate is preferably a copper substrate or copper sputter substrate which is strongly influenced by copper.

The thick film photoresist laminate can be produced, for example, in the following manner.

That is, a solution of the positive photoresist composition thus obtained as described above is coated on a substrate and the solvent is removed by heating to form a desired coating film. As the method of coating on a substrate to be treated, for example, there can be employed methods such as a spin coating method, slit coating method, roll coating method, screen printing method and applicator method. Although prebaking conditions of the coating film of the present invention vary depending on the kind and content of the respective components in the composition as well as the thickness of the coating film, prebaking is usually conducted at a temperature within a range from 70 to 150° C., and preferably from 80 to 140° C., for about 2 to 60 minutes.

The thickness of the thick film photoresist layer is within a range from 10 to 150 μm, preferably from 20 to 120 μm, and more preferably from 20 to 80 μm.

To form a resist pattern using the thick film photoresist laminate thus obtained, the resulting thick film photoresist layer is selectively irradiated with light (exposure) having one or more wavelengths selected from g-rays (wavelength: 436 nm), h-rays (wavelength: 405 nm) and i-rays (wavelength: 365 nm) through a mask having a predetermined pattern.

In view of sensitivity, light preferably contains i-rays.

As used herein, active rays means rays which activate an acid generator so as to generate an acid. As a radiation source of radiation, for example, a low-pressure mercury lamp, a high-pressure mercury lamp, an ultrahigh-pressure air gun mercury lamp, a metal halide lamp and an argon gas laser can be used.

Among these lamps, an ultrahigh-pressure air gun mercury lamp is preferably used and its energy amount is preferably from 100 to 10,000 mJ/cm².

After the exposure, diffusion of the acid is promoted by heating using a known method, thereby varying the alkali solubility of the thick film photoresist layer of this exposed portion.

Then, the non-exposed portion is dissolved and removed by using a predetermined aqueous alkali solution as a developing solution to obtain a predetermined resist pattern. As the developing solution, for example, an aqueous solution of alkalis can be used such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5,4,0]-7-undecene and 1,5-diazabicyclo[4,3,0]-5-nonane. Also an aqueous solution prepared by adding a water-soluble organic solvent such as methanol or ethanol and a surfactant to an aqueous solution of alkalis can be used as the developing solution.

The developing time varies depending on the kind and content of the respective components in the composition as well as the thickness of the dry coating film of the composition, but is usually from 1 to 30 minutes. The developing method may be any of a liquid building-up method, dipping method, paddle method and spray developing method. After the development, the resist pattern is washed with running water for 30 to 90 seconds and then dried using an air gun or an oven.

Then, a connecting terminal such as a metal post or bump can be formed by embedding a conductor such as metal into the non-resist portion (portion removed by an alkali developing solution) of the resist pattern thus obtained, using plating. The plating method is not specifically limited and various conventionally known methods can be employed. As the plating solution, solder plating, copper plating, gold plating and nickel plating solutions are particularly preferably used.

Finally, the residual resist pattern is removed by a conventional method using a remover.

As described above, the present invention can provide a positive photoresist composition capable of forming a resist pattern even on a substrate in which copper exists on the surface on which a photoresist layer is formed, a thick film photoresist laminate, a method for producing a thick film resist pattern, and a method for producing a connecting terminal.

Therefore, the positive photoresist composition of the present invention is preferably used for a thick film. Also the positive photoresist composition is preferably used for a substrate in which copper exists in the surface on which a photoresist layer is formed.

The component (A1) is characterized in that it can stably exist on copper and also shows an absorption in light having one or more wavelengths selected from g-rays, h-rays and i-rays.

### EXAMPLES

Examples of the present invention will now be described, but the scope of the present invention is not limited to the following examples.

### Synthesis Example 1

### (B-1) Synthesis of Resin Whose Solubility in Alkali is Enhanced by the Action of an Acid

After replacing the atmosphere in a flask equipped with a stirrer, a reflux condenser, a thermometer and a dropping tank, propylene glycol methyl ether acetate as a solvent was charged and stirring was started. Then, the temperature of the solvent was raised to 80° C. In the dropping tank, 2,2′-azobisisobutyronitrile as a polymerization catalyst, and 30 mol % of a 2-methoxyethyl acrylate constituent unit, 10 mol % of an n-butyl acrylate constituent unit, 55 mol % of a 2-ethyl-2-adamanthyl methacrylate constituent unit represented by the following chemical formula and 5 mol % of an acrylic acid constituent unit as constituent units were charged, followed by stirring until the polymerization catalyst dissolved. This solution was uniformly added dropwise in a flask for 3 hours and then polymerized at 80° C. for 5 hours. The reaction product was cooled to room temperature and then fractionated to obtain a resin (B-1) having a mass average molecular weight of 30,000.

### Synthesis Example 2

### (B-2) Synthesis of Resin Whose Solubility in an Alkali is Enhanced by the Action of an Acid

In the same manner as in Synthesis Example 1, except that 30 mol % of a 2-methoxyethyl acrylate constituent unit, 10 mol % of an n-butylacrylic acid constituent unit, 55 mol % of a 2-ethyl-2-adamanthyl methacrylate constituent unit represented by the following chemical formula and 5 mol % of an acrylic acid constituent unit were used as constituent units, a resin (B-2) having a mass average molecular weight of 100,000 was obtained.

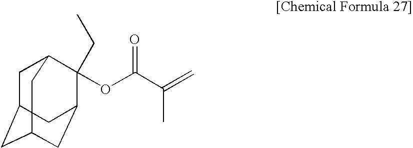

### Synthesis Example 3

### (C-1) Synthesis of a Copolymer of a Hydroxystyrene Constituent Unit and Styrene Constituent Unit

In the same manner as in Synthesis Example 1, except that 10 mol % of a hydroxystyrene constituent unit and 90 mol % of a styrene constituent unit were used as constituent units, a resin (C-1) having a mass average molecular weight of 1,500 was obtained.

### Synthesis Example 4

### (C-2) Synthesis of Novolak Resin

m-cresol and p-cresol were mixed in a mass ratio of 60:40 and, after adding formalin, the mixture was condensed by a conventional method using an oxalic acid catalyst to obtain a cresol novolak resin. The resulting resin was fractionated, thereby eliminating a low molecular range, and thus a novolak resin having a mass average molecular weight of 15,000 was obtained. This resin is referred to as a resin (C-2).

### Examples

The respective components shown in Table 1 (unit indicates parts by mass in the table) were mixed with propylene glycol monomethyl ether acetate to obtain a uniform solution, and then the solution was filtered through a membrane filter having a pore size of 1 μm to obtain a chemically-amplified positive photoresist composition.

TABLE 1

| | Examples | | | | |
|---|---|---|---|---|---|
| | 1 | 2 | 3 | 4 | 5 |
| A-1 | 2 | 2 | | | 2 |
| A-2 | | | 2 | 2 | |
| B-1 | 40 | | 40 | | 40 |
| B-2 | | 40 | | 40 | |
| C-1 | 10 | 10 | 10 | 10 | 10 |
| C-2 | 50 | 50 | 50 | 50 | 50 |
| D-1 | 0.1 | 0.1 | 0.1 | 0.1 | |
| D-2 | 0.1 | 0.1 | 0.1 | 0.1 | |

Symbols in the Table 1 are as follows.

(A-1): Compound represented by the chemical formula (A1-9)
(A-2): Compound represented by the chemical formula (A1-10)
(B-1): Copolymer mass having an average molecular weight of 30,000, comprising 30 mol % of a 2-methoxyethyl acrylate unit, 10 mol % of a constituent unit derived from n-butyl acrylate, 55 mol % of a constituent unit derived from 2-ethyl-2-adamanthyl methacrylate represented by the following chemical formula, and 5 mol % of a constituent unit derived from acrylic acid
(B-2): Copolymer having a mass average molecular weight of 100,000, comprising 30 mol % of a constituent unit derived from 2-methoxyethyl acrylate, 10 mol % of a constituent unit derived from n-butyl acrylate, 55 mol % of a constituent unit derived from 2-ethyl-2-adamanthyl methacrylate represented by the following chemical formula, and 5 mol % of a constituent unit derived from acrylic acid
(C-1): Copolymer (mass average molecular weight: 1,500) comprising 10 mol % of a hydroxystyrene unit and 90 mol % of a styrene unit
(C-2): Novolak resin (mass average molecular weight: 15,000)

### (D-1) Triethanolamine

(D-2) Salicylic acid

### [Evaluation]

Using the photoresist compositions prepared in the above examples, characteristics were evaluated. As shown in Table 2, regarding the thickness of a photoresist layer, both 20 μm and 100 μm were evaluated.

### Compatibility

Each composition was mixed under stirring at room temperature for 12 hours. Immediately after stirring for 12 hours, the dissolved state was visually observed. The dispersed state was evaluated according to the following criteria.

A: It was visually confirmed that the composition was uniformly dispersed after stirring for 12 hours.
B: The composition was uniformly dispersed after stirring for 12 hours, but caused phase separation after standing for 12 hours.
C: The composition was not uniformly dispersed after stirring for 12 hours.

### Coatability

On a 5-inch Cu sputtering wafer, each composition was coated at 1000 rpm for 25 seconds, using a spinner, and then heated on a hot plate at 130° C. for 6 minutes. The coating film thus formed was visually observed and coatability was evaluated according to the following criteria.

A: The resulting coating film is free from unevenness and is uniform.
B: The resulting coating film is inferior in flatness and is not uniform.
C: The resulting coating film has unevenness such as pinholes or cissing.

### Substrate Dependence

In the case of a 20-μm thick film, on a 5-inch Si, Au, Cu, Ni or Al sputtering wafer, each composition was coated at 1000 rpm for 25 seconds, using a spinner, and then prebaked on a hot plate at 130° C. for 6 minutes to form a thick film photoresist laminate. In the case of a 100-μm thick film, each composition was coated at 500 rpm for 10 seconds and then prebaked in an oven at 120° C. for 60 minutes to form a thick film photoresist laminate.

The thick film photoresist laminate thus obtained was stepwisely exposed to ultraviolet rays within a range from 100 to 10,000 mJ/cm² through a pattern mask for measurement of resolution using an aligner (manufactured by Canon Inc. under the trade name of PLA501F). After the exposure, the exposed photoresist laminate was heated at 80° C. for 5 minutes and then developed with a developing solution (manufactured by TOKYO OHKA KOGYO CO., LTD. under the trade name of PMER series, P-7G).

The wavelength of the exposure light is a mixture of g-rays, h-rays and i-rays.

Then, the photoresist laminate was washed with running water, followed by nitrogen blowing to obtain a patterned cured article. The resulting patterned cured article was observed by a microscope and substrate dependence was evaluated according to the following criteria.

A: A patterned cured article can be obtained by using any of Si, Au, Cu, Ni and Al substrates.
B: A patterned cured article cannot be obtained by using a Cu substrate.
C: A patterned cured article cannot be obtained by using substrates other than the Cu substrate, but can be obtained using the Cu.

### Developing Properties

In the case of a 20-μm thick film, on a 5-inch Cu sputtering wafer, each composition was coated at 1000 rpm for 25 seconds, using a spinner, and then prebaked on a hot plate at 130° C. for 6 minutes to form a thick film photoresist laminate. In the case of a 100-μm thick film, each composition was coated at 500 rpm for 10 seconds and then prebaked in an oven at 120° C. for 60 minutes to form a thick film photoresist laminate.

The thick film photoresist laminate thus obtained was stepwisely exposed to ultraviolet rays within a range from 100 to 10,000 mJ/cm² through a pattern mask for measurement of resolution using an aligner (manufactured by Canon Inc. under the trade name of PLA501F). After the exposure, the exposed photoresist laminate was heated at 80° C. for 5 minutes and then developed with a developing solution (manufactured by TOKYO OHKA KOGYO CO., LTD. under the trade name of PMER series, P-7G).

The wavelength of exposure light is a mixture of g-rays, h-rays and i-rays.

Then, the photoresist laminate was washed with running water, followed by nitrogen blowing to obtain a patterned cured article. The resulting patterned cured article was observed by a microscope and developing properties and resolution were evaluated according to the following criteria.

A: A pattern having an aspect ratio of 2 or more was formed in any dose described above and no residue was recognized.
C: A pattern having an aspect ratio of less than 2 was not formed or a residue was recognized.

The aspect ratio indicates (height of resist on pattern/width of resist on pattern).

### Photosensitivity

On a 5-inch Cu sputtering wafer, coating films having different thicknesses were formed in the same manner as in case of the test of developing properties, and then each of thick film photoresist laminate thus obtained was division-exposed to light within a range from 100 to 10,000 mJ/cm² through a pattern mask for measurement of resolution using an aligner (manufactured by Canon Inc. under the trade name of PLA501F). After the exposure, the exposed photoresist laminate was developed with a developing solution (manufactured by TOKYO OHKA KOGYO CO., LTD. under the trade name of PMER series, P-7G). Then, the photoresist laminate was washed with running water, followed by nitrogen blowing to obtain a patterned cured article. The resulting patterned cured article was observed by a microscope and the dose required to form a pattern having an aspect ratio of 2 or less and to eliminate the residue, that is, the minimum dose required to form a pattern was measured.

The positive photoresist compositions thus prepared in Examples 1 to 5 were subjected to the above respective tests and evaluated. The results are shown in Table 2. The number of the resist formulation corresponds to the number described in Table 1.

TABLE 2

| Formulation of | Examples | | | | | | | | | |
|---|---|---|---|---|---|---|---|---|---|---|
| resist | 1 | 1 | 2 | 2 | 3 | 3 | 4 | 4 | 5 | 5 |
| Film thickness | 20 | 100 | 20 | 100 | 20 | 100 | 20 | 100 | 20 | 100 |
| (μm) | | | | | | | | | | |
| Compatibility | A | A | A | A | A | A | A | A | A | A |
| Coatability | A | A | A | A | A | A | A | A | A | A |
| Substrate | A | A | A | A | A | A | A | A | A | A |
| dependence | | | | | | | | | | |
| Devoloping | A | A | A | A | A | A | A | A | A | A |
| properties | | | | | | | | | | |
| Photosensitivity | 450 | 3000 | 450 | 3000 | 300 | 2500 | 300 | 2500 | 150 | 1000 |

### Comparative Examples

The respective components shown in Table 3 (unit indicates parts by mass in the table) were mixed with propylene glycol monomethyl ether acetate to obtain a uniform solution, and then the solution was filtered through a membrane filter having a pore size of 1 μm to obtain a chemically-amplified positive photoresist composition.

TABLE 3

Comparative
Examples

| | 1 | 2 | 3 | 4 |
|---|---|---|---|---|
| A-3 | 1 | 1 | | |
| A-4 | | | 1 | 1 |
| B-1 | 40 | | 40 | |
| B-2 | | 40 | | 40 |
| B-3 | 10 | 10 | 10 | 10 |
| C-1 | 50 | 50 | 50 | 50 |
| D-1 | 0.1 | 0.1 | 0.1 | 0.1 |
| D-2 | 0.1 | 0.1 | 0.1 | 0.1 |

In the table, (A-3) and (A-4) are compounds represented by the following chemical formulas, respectively. Other components are the same as those shown in Table 1.

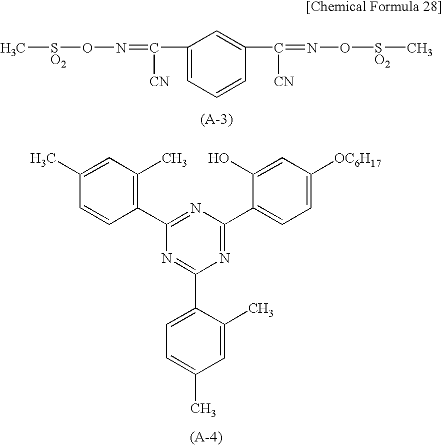

In the same manner as in examples, evaluation was conducted. The results are shown in Table 4. The number of the formulation of the resist corresponds to the number described in Table 3.

TABLE 4

| Formulation of | Comparative Examples | | | | | | | |
|---|---|---|---|---|---|---|---|---|
| resist | 1 | 1 | 2 | 2 | 3 | 3 | 4 | 4 |
| Film thickness | 20 | 100 | 20 | 100 | 20 | 100 | 20 | 100 |
| (μm) | | | | | | | | |
| Compatibility | A | A | A | A | A | A | A | A |
| Coatability | A | A | A | A | A | A | A | A |
| Substrate | B | B | B | B | B | B | B | B |
| dependence | | | | | | | | |
| Devolopability | A | A | A | A | A | A | A | A |
| Photo- | 450 | 3000 | 450 | 3000 | 300 | 2500 | 300 | 2500 |
| sensitivity | | | | | | | | |

It could be confirmed by the results shown in Table 2 and Table 4 that the resist composition of the present invention makes it possible to obtain a good resist pattern without using a shielding layer even when copper exists on a substrate.

The resist composition of the present invention can be applied to a thick film photoresist laminate, the production of the thick film resist pattern, and the production of a connecting terminal.

1. A positive photoresist composition for exposing to light having one or more wavelengths selected from g-rays, h-rays and i-rays, comprising:
(A) a compound which generates an acid under irradiation with active rays or radiation, and
(B) a resin whose solubility in an alkali is enhanced by an action of an acid, wherein
the component (A) contains an onium salt (A1) having a naphthalene ring in a cation moiety.

2. The positive photoresist composition according to claim 1, which is used for a thick film.

3. The positive photoresist composition according to claim 1, which is used for a substrate containing copper in the surface on which a photoresist layer is formed.

4. The positive photoresist composition according to claim 1, wherein the cation moiety of the component (A1) is represented by the following general formula (A1): 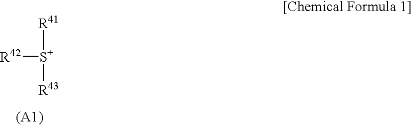
wherein at least one of R⁴¹, R⁴² and R⁴³ represents a group represented by the following general formula (A1-0) and the others represent a linear or branched chain alkyl group having 1 to 4 carbon atoms, a phenyl group which may have a substituent, a hydroxyl group, or a linear or branched chain alkoxy group having 1 to 4 carbon atoms; or at least one of R⁴¹, R⁴² and R⁴³ represents a group represented by the following general formula (A1-0) and the other two substituents each independently represents a linear or branched chain alkylene group having 1 to 4 carbon atoms, and ends thereof may be combined to form a ring; 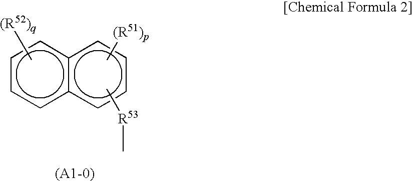
wherein R⁵¹ and R⁵² each independently represents a hydroxyl group, a linear or branched chain alkoxy group having 1 to 4 carbon atoms, or a linear or branched chain alkyl group having 1 to 4 carbon atoms; R⁵³ represents a single bond or a linear or branched chain alkylene group having 1 to 4 carbon atoms which may have a substituent; and p and q each independently represents an integer of 0 or 1 to 2, and p+q is 3 or less and may also be the same or different from each other when a plurality of R⁵¹ exists, or may be the same or different from each other when a plurality of R⁵² exists.

5. The positive photoresist composition according to claim 1, wherein the component (A1) is a sulfonium salt.

6. The positive photoresist composition according to claim 1, further comprising (C) an alkali-soluble resin.

7. The positive photoresist composition according to claim 1, further comprising (D) an acid diffusion inhibitor.

8. A thick film photoresist laminate comprising a substrate and a thick film photoresist layer having a thickness of 10 to 150 μm made of the positive photoresist composition according to claim 1, which are laminated with each other.

9. The thick film photoresist laminate according to claim 8, wherein the substrate is a substrate containing copper in the surface on which the photoresist layer is formed.

10. A method for producing a thick film resist pattern which comprises a lamination step of obtaining the thick film photoresist laminate according to claim 8, an exposure step of selectively exposing the thick film photoresist laminate to light having one or more wavelengths selected from g-rays, h-rays and i-rays, and a development step of developing after the exposure step to obtain a thick film resist pattern.

11. A method for producing a connecting terminal which comprises the step of forming a connecting terminal made of a conductor at a non-resist portion of a thick film resist pattern obtained by the method for producing a thick film resist pattern according to claim 10.

12. The method for producing a connecting terminal according to claim 11 which uses the thick film resist pattern formed on the substrate containing copper in the surface on which the photoresist layer is formed.
